(19) United States
(12) Patent Application Publication
(10) Pub. No.: US 2026/0018215 A1
(43) Pub. Date: Jan. 15, 2026

(54) MEMORY DEVICE FOR ADJUSTING TRIP LEVEL AND OPERATING METHOD THEREOF

(71) Applicant: SAMSUNG ELECTRONICS CO., LTD., Suwon-si (KR)

(72) Inventors: Gangmin Lee, Suwon-si (KR); Seunghoon Shin, Suwon-si (KR); Yoon-Hee Choi, Suwon-si (KR); Cheon An Lee, Suwon-si (KR)

(21) Appl. No.: 19/183,080

(22) Filed: Apr. 18, 2025

(30) Foreign Application Priority Data
Jul. 10, 2024 (KR) 10-2024-0091226

(51) Int. Cl. G11C 16/26; G11C 16/08; G11C 16/30

(52) U.S. Cl. CPC G11C 16/26; G11C 16/08; G11C 16/30

(57) ABSTRACT

A memory device for adjusting a trip level and an operating method thereof are provided. The memory device includes a cell string including memory cells, and a page buffer connected to the cell string through a bit line and configured to sense data of a selected memory cell of the memory cells through a sensing latch circuit, where the sensing latch circuit includes a sensing latch including a first inverter and a second inverter, and a trim transistor circuit electrically connected to a p-type metal oxide semiconductor (PMOS) transistor of the first inverter and configured to adjust a trip level of the sensing latch based on a trim voltage.

### CROSS-REFERENCE TO RELATED APPLICATIONS

This application claims the benefit under 35 USC § 119(a) of Korean Patent Application No. 10-2024-0091226, filed on Jul. 10, 2024, in the Korean Intellectual Property Office, the entire disclosure of which is incorporated herein by reference for all purposes.

### BACKGROUND

A memory may include a volatile memory and a non-volatile memory. For example, flash memory may be one of non-volatile memories, and may maintain stored data without power supply. A flash memory technique may be an electrically erasable programmable read-only memory (EEPROM), and may electrically erase and write the data. The flash memory may be used by various electronic devices, mainly by a computer, a smartphone, a camera, a universal serial drive (USB) drive, and a solid state drive (SSD). A page buffer may be used for data sensing of the flash memory. Each bit line of the flash memory may be connected to the page buffer, and data stored in each memory cell of each bit line may be sensed using the page buffer.

### SUMMARY

A trip operation of a sensing latch may be used for data sensing of a memory (e.g., flash memory). The trip operation may be based on a pull up operation and a pull down operation of a p-type metal oxide semiconductor (PMOS) transistor and an n-type metal oxide semiconductor (NMOS) transistor. A process voltage temperature (PVT) variation of the PMOS transistor and the NMOS transistor may cause a variation of a trip level for the trip operation. The variation of the trip level may hinder securing a required sensing margin (e.g., a sensing margin for a low power operation).

In some implementations, a memory device includes a cell string including memory cells, and a page buffer connected to the cell string through a bit line and comprising a sense latch circuit. The page buffer is configured to sense data of a selected memory cell of the memory cells using the sensing latch circuit, wherein the sensing latch circuit includes a sensing latch including a first inverter and a second inverter, and a trim transistor circuit electrically connected to a PMOS transistor of the first inverter and configured to adjust a trip level of the sensing latch based on a trim voltage.

In some implementations, a memory device includes a cell string including memory cells, and a page buffer connected to the cell string through a bit line and comprising a sense latch circuit. The page buffer is configured to sense data of a selected memory cell of the memory cells using the sensing latch circuit, wherein the sensing latch circuit includes a sensing latch disposed between a latch node and an inverting latch node, a sensing transistor disposed between the latch node and a ground terminal, and a trim transistor circuit connected to the sensing transistor in series and configured to adjust a trip level of the sensing latch based on a trim voltage.

In some implementations, a memory device includes a cell string including memory cells, and a page buffer connected to the cell string through a bit line and comprising a sense latch circuit. The page buffer is configured to sense data of a selected memory cell of the memory cells using the sensing latch circuit, wherein the sensing latch circuit includes a sensing latch disposed between a latch node and an inverting latch node and including a first inverter and a second inverter, a sensing transistor disposed between the latch node and a ground terminal, and a trim transistor circuit configured to adjust a trip level of the sensing latch based on a trim voltage, wherein the trim transistor circuit includes a first trim transistor circuit electrically connected to a PMOS transistor of the first inverter and a second trim transistor circuit electrically connected to the sensing transistor.

In some implementations, a required sensing margin may be secured by controlling a trip operation using a trim transistor circuit added to a sensing latch circuit. In some implementations, a trim voltage for controlling a trip operation may be automatically determined using a sample sensing latch circuit corresponding to a sensing latch circuit.

Other features and aspects will be apparent from the following detailed description, the drawings, and the claims.

### BRIEF DESCRIPTION OF THE DRAWINGS

FIG. 1 is a block diagram of an example configuration of a memory device.

FIG. 2 is a circuit diagram of an example configuration of a memory block of a memory cell array.

FIG. 3 is a circuit diagram of an example configuration of a cell string of a memory block.

FIG. 4 is a circuit diagram of an example configuration of a sensing latch circuit diagram including a first trim transistor circuit and a second trim transistor circuit.

FIG. 5 is a graph illustrating an example of an on-cell margin, an off-cell margin, and a trip level variation.

FIGS. 6 and 7 are circuit diagrams of an example configuration of a sensing latch circuit diagram having one of a first trim transistor circuit and a second trim transistor circuit.

FIG. 8 is a circuit diagram of an example configuration of a sensing latch circuit with parallel trim transistors.

FIG. 9 is a circuit diagram of an example configuration of a sensing latch circuit diagram including a second trim transistor circuit positioned between a latch node and a sensing transistor.

FIG. 10 is a circuit diagram of an example configuration of a sensing latch circuit diagram including a first trim transistor circuit positioned inside an inverter of a sensing latch.

FIG. 11 is a circuit diagram of an example configuration of a sensing latch circuit diagram including a first trim transistor circuit and a second trim transistor circuit each including at least one trim transistor.

FIG. 12 is a circuit diagram of an example configuration performing a calibration procedure using a sample sensing latch circuit.

FIG. 13 is a circuit diagram of an example configuration of a page buffer.

FIG. 14 is a flowchart illustrating an example of a method performed by a memory device.

Throughout the drawings and the detailed description, unless otherwise described or provided, the same drawing reference numerals may refer to the same elements, features, and structures. The drawings may not be to scale, and the relative size, proportions, and depiction of elements in the drawings may be exaggerated for clarity, illustration, and convenience.

### DETAILED DESCRIPTION

Hereinafter, implementations will be described in detail with reference to the accompanying drawings. When describing the implementations with reference to the accompanying drawings, like reference numerals refer to like elements and a repeated description related thereto will be omitted.

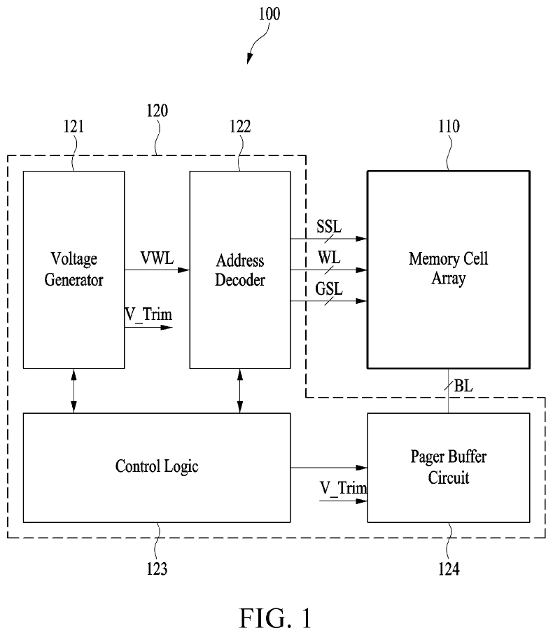

FIG. 1 is a block diagram of an example configuration of a memory device according to some implementations. Referring to FIG. 1, a memory device 100 may include a memory cell array 110 and a peripheral circuit 120. The peripheral circuit 120 may include a voltage generator 121, an address decoder 122, a control logic 123, and a page buffer circuit 124. The peripheral circuit 120 may further include additional components (e.g., a column logic, a pre-decoder, a temperature sensor, a command decoder, an address decoder, and an input/output interface) that are not shown in FIG. 1. Although not shown in FIG. 1, the memory device 100 may further include a controller (e.g., a memory controller) configured to control the memory device 100. For example, the controller may control a program operation, a read operation, and an erase operation with respect to the memory cell array 110 in response to a request of a host device (e.g., a processor, such as a central processing unit (CPU)).

The memory cell array 110 may be connected to the page buffer circuit 124 through bit lines BL and may be connected to the address decoder 122 through string selection lines SSL, word lines WL, and ground selection lines GSL.

The memory cell array 110 may include memory cells. Multi-bit data may be stored in each memory cell. For example, the memory cells may be flash memory cells. In this case, the memory device 100 may correspond to a flash memory device. In this case, the memory device 100 may be a non-volatile memory device, such as a solid state drive (SSD) and a universal serial bus (USB) drive. Hereinafter, an example in which the memory cells are NAND flash memory cells may be described, but the example is not limited thereto. For example, the memory cells may be different memory cells, such as resistive random access memory (ReRAM), phase change RAM (PRAM), ferroelectric RAM (FRAM), or magnetic RAM (MRAM).

The memory cell array 110 may include a 3D cell array. The 3D cell array may include cell strings. Each cell string may include memory cells. The memory cells of each cell string may be respectively connected to word lines WL vertically stacked on a substrate. The memory cell array 110 may be divided into memory blocks. Each memory block may include a 3D cell array having a predetermined size.

The control logic 123 may generate various control signals for a program operation, a read operation, and an erase operation. For example, the control signal may include a voltage control signal, an address signal, and the like. The control logic 123 may generally control various operations in the memory device 100.

The voltage generator 121 may generate various voltages for performing the program, read, and erase operations on the memory cell array 110 under the control of the control logic 123. For example, the voltage generator 121 may generate a word line voltage VWL. The voltage generator 121 may generate a program voltage, a read voltage, a pass voltage, an erase verification voltage, and a program verification voltage. In addition, the voltage generator 121 may generate a string selection line voltage and a ground selection line voltage under the control of the control logic 123. In addition, the voltage generator 121 may generate one or more voltages to drive or control the page buffer circuit 124. For example, the voltage generator 121 may generate a trim voltage V_Trim provided to each page buffer of the page buffer circuit 124.

The address decoder 122 may perform a selection operation on the word lines WL and a selection operation on the string selection lines SSL based on an address signal (e.g., a row address signal). The page buffer circuit 124 may perform a selection operation on bit lines BL based on an address signal (e.g., a column address signal). Each page buffer PB of the page buffer circuit 124 may operate as a write driver or a sensing amplifier according to an operation mode.

The page buffer circuit 124 may include page buffers connected to the bit lines BL. Each page buffer may be connected to a corresponding bit line of the bit lines BL. The page buffer circuit 124 may temporarily store data read from the memory cell array 110 and data to be programmed on the memory cell array 110.

Each page buffer may include at least one latch. Each latch may temporarily store data. For example, each latch may include a sensing latch. The sensing latch may be connected to a sensing node. During a data sensing operation, a bit line and a sensing node (e.g., a sensing capacitor of the sensing node) may be precharged, a voltage of the sensing node may be developed (e.g., changed) according to a logic state of the data stored in the memory cell, and the data may be stored in the sensing latch connected to the sensing node as the voltage of the sensing node is developed.

The data sensing may be performed using a trip operation of the sensing latch. The trip operation may be based on pull up and pull down operations of a p-type metal oxide semiconductor (PMOS) transistor and an n-type MOS (NMOS) transistor. A trip level may be defined for the trip operation, and data having different logic states may be stored in the sensing latch based on whether a voltage of the developed sensing node is less than or greater than the trip level. The process-voltage-temperature (PVT) variation of the PMOS transistor and the NMOS transistor may cause a variation of the trip level. The trip level variation may impede securing a required sensing margin (e.g., a sensing margin for a low-power operation).

In some implementations, a trip level of the sensing latch is adjusted using a trim transistor circuit added to the sensing latch circuit. More specifically, each page buffer of the page buffer circuit 124 may include a sensing latch circuit, and the sensing latch circuit of the page buffer may include a sensing latch and a trim transistor circuit. The trim transistor circuit may adjust the trip level of the sensing latch based on a trim voltage V_Trim. Due to this, a required sensing margin may be secured.

In some implementations, the trim voltage V_Trim is automatically determined in a calibration procedure using a sample sensing latch circuit corresponding to the sensing latch circuit. The sample sensing latch circuit may have the same configuration and the same structure as the sensing latch circuit. A voltage that trips a sample sensing latch at a target trip level may be determined to be the trim voltage V_Trim, and a trip operation of the sensing latch may be induced by providing the trim voltage V_Trim to the sensing latch circuit. The sensing latch circuit and the sample sensing latch circuit may be manufactured on the same wafer. The PVT variation of the sensing latch circuit and the PVT variation of the sample sensing latch circuit may have corresponding levels. Thus, the trip operation of the sensing latch circuit may be induced by the same trim voltage that trips the sample sensing latch circuit.

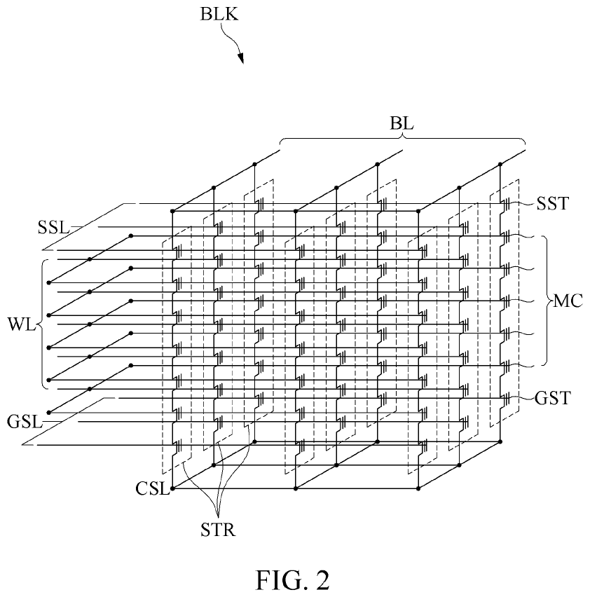

FIG. 2 is a circuit diagram of an example configuration of a memory block of a memory cell array according to some implementations. Referring to FIG. 2, a memory block BLK may include cell strings STR formed between bit lines BL and a common source line CSL. Each cell string may include a string selection transistor SST, memory cells MC, and a ground selection transistor (GST). The memory block BLK may be one of memory blocks of a memory cell array (e.g., the memory cell array 110 of FIG. 1).

The string selection transistors SST may be connected to the string selection lines SSL. The ground selection transistors GST may be connected to the ground selection lines GSL. The string selection transistors SST may be connected to the bit lines BL, and the ground selection transistors GST may be connected to the common source line CSL.

The memory cells MC may be connected to the word lines WL. The word lines WL may be positioned above the ground selection lines GSL. The memory cells MC at the same or substantially similar height from a substrate may be connected to the word lines WL, respectively. Each of the word lines WL may be a selected word line sWL or an unselected word line uWL. Each of the memory cells may be a selected memory cell sMC or an unselected memory cell uMC. For example, when a z-th word line is selected from the word lines WL, the z-th word line may be an sWL and the other word lines may be uWLs. A z-th memory cell connected to the z-th word line may be an sMC, and a memory cell connected to the other word line may be a uMC.

The bit lines BL may be connected to the page buffers. Each page buffer may be connected to a corresponding bit line of the bit lines BL.

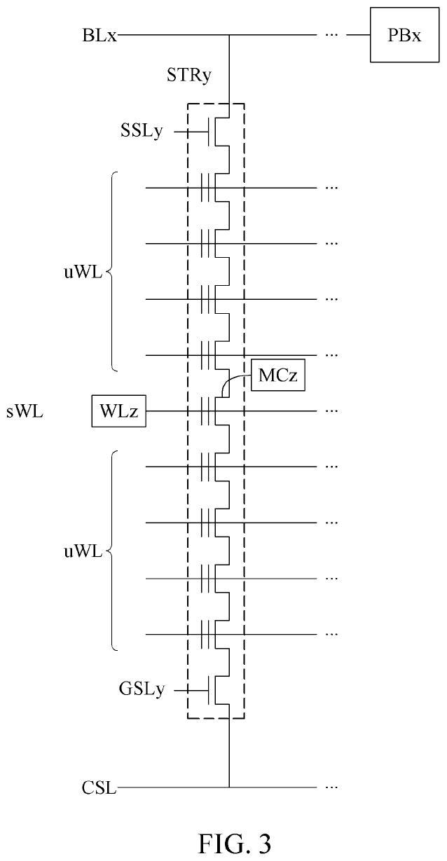

FIG. 3 is a circuit diagram of an example configuration of a cell string of a memory block according to some implementations. FIG. 3 may correspond to an example in which an x-th bit line BLx, a y-th cell string STRy, and a z-th word line WLz are selected in the memory block BLK of FIG. 2. Referring to FIG. 3, the y-th cell string STRy may be selected by a y-th string selection line SSLy and a y-th ground selection line GSLy. A z-th memory cell MCz may be selected by the z-th word line WLz. The z-th word line WLz may correspond to a selected word line and the other word lines of the y-th cell string STRy may correspond to unselected word lines. The z-th memory cell MCz may correspond to a selected memory cell, and the other memory cells of the y-th cell string STRy may correspond to unselected memory cells.

The y-th cell string STRy may include memory cells. An x-th page buffer PBx may be connected to the y-th cell string STRy through the x-th bit line BLx. The x-th page buffer PBx may include one or more latch circuits. For example, the latch circuit may include a sensing latch circuit. The x-th page buffer PBx may sense data of a selected memory cell (e.g., the z-th memory cell MCz) among the memory cells using the sensing latch circuit.

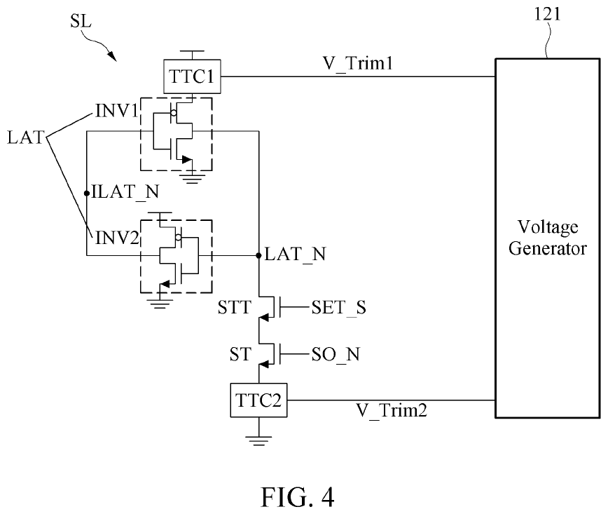

FIG. 4 is a circuit diagram of an example configuration of a sensing latch circuit diagram including a first trim transistor circuit and a second trim transistor circuit according to some implementations. Referring to FIG. 4, a sensing latch circuit SL may include a sensing latch LAT, a first trim transistor circuit TTC1, a second trim transistor circuit TTC2, a latch set transistor STT, and a sensing transistor ST. Although not shown in FIG. 4, the sensing latch circuit SL may further include other components, such as a latch reset transistor.

The sensing latch LAT may be disposed between a latch node LAT_N and an inverting latch node ILAT_N, and may include a first inverter INV1 and a second inverter INV2. The first inverter INV1 and the second inverter INV2 may each include a PMOS transistor and an NMOS transistor.

The latch set transistor STT may receive a latch set signal SET_s via a gate. The latch set transistor STT may set the latch node LAT_N based on the latch set signal SET_S. The sensing transistor ST may be disposed between the latch node LAT_N and a ground terminal. A gate of the sensing transistor ST may be connected to a sensing node SO_N. The latch set transistor STT and the sensing transistor ST may each consist of an NMOS transistor.

The first trim transistor circuit TTC1 and the second trim transistor circuit TTC2 may form a trim transistor circuit. The trim transistor circuit may adjust a trip level of the sensing latch LAT based on a trim voltage. The trim voltage may be provided by the voltage generator 121. The trim voltage may include a first trim voltage V_Trim1 and a second trim voltage V_Trim2. The first trim transistor circuit TTC1 may be electrically connected to the PMOS transistor of the first inverter INV1. The second trim transistor circuit TTC2 may be electrically connected to the sensing transistor ST.

The first trim transistor circuit TTC1 may be disposed between a power terminal and the PMOS transistor of the first inverter INV1 or between the PMOS transistor of the first inverter INV1 and the NMOS transistor of the first inverter INV1. FIG. 4 illustrates an example in which the first trim transistor circuit TTC1 is disposed between the power terminal and the PMOS transistor of the first inverter INV1. Although not shown, it is to be understood that the first trim transistor circuit TTC1 may be disposed between the PMOS transistor of the first inverter INV1 and the NMOS transistor of the first inverter INV1.

The first trim transistor circuit TTC1 may include one or more first trim transistors. The first trim transistor may receive the first trim voltage V_Trim1 via a gate. The first trim transistor may be a PMOS transistor. The first trim transistor circuit TTC1 may include a plurality of first trim transistors, and the plurality of first trim transistors may be connected in series or in parallel.

The second trim transistor circuit TTC2 may be disposed between the latch node LAT_N and the ground terminal. For example, the second trim transistor circuit TTC2 may be disposed between the sensing transistor ST and the ground terminal or between the latch node LAT_N and the sensing transistor ST. FIG. 4 illustrates an example in which the second trim transistor circuit TTC2 is disposed between the sensing transistor ST and the ground terminal. Although not show in FIG. 4, it is to be understood that the second trim transistor circuit TTC2 may be disposed between the latch node LAT_N and the sensing transistor ST.

The second trim transistor circuit TTC2 may include one or more second trim transistors. The second trim transistor may receive a second trim voltage V_Trim2 via a gate. The second trim transistor may be an NMOS transistor. The second trim transistor circuit TTC2 may include a plurality of second trim transistors, and the plurality of second trim transistors may be connected in series or in parallel.

The PMOS transistor of the first inverter INV1 may perform a pull up operation and the sensing transistor ST may perform a pull down operation. The sensing latch LAT may be tripped based on P/N fighting according to the pull up operation of the PMOS transistor of the first inverter INV1 and the pull down operation of the sensing transistor ST. The P/N fighting may be affected by the PVT variation of the sensing transistor ST and the PMOS transistor, and the PVT variation may cause a variation of a trip level for a trip operation of the sensing latch LAT. The trip level variation may impede securing a required sensing margin (e.g., a sensing margin for a low-power operation). In some implementations, a required sensing margin is secured by adjusting the P/N strength using the trim transistor circuit.

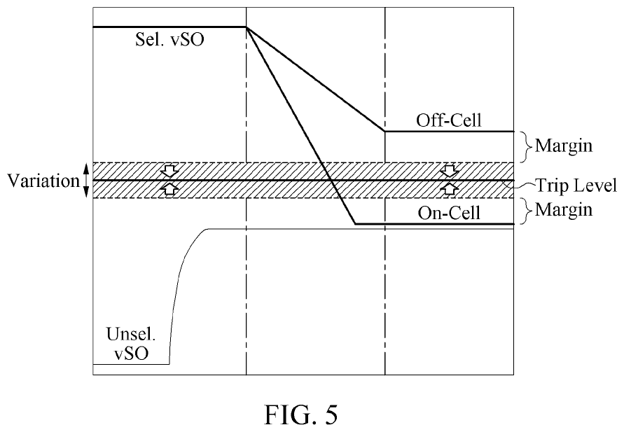

FIG. 5 is a graph illustrating an on-cell margin, an off-cell margin, and a trip level variation according to some implementations. Referring to FIG. 5, during a data sensing operation, a voltage Selected. vSO (also called Sel. vSO in the present disclosure) of a sensing node (e.g., the SO_N of FIG. 4) of a page buffer connected to a selected bit line and a voltage Unselected. vSO (also called Unsel. vSO in the present disclosure) of a sensing node of a page buffer connected to an unselected bit line are illustrated. During the data sensing operation, a bit line (e.g., BLx in FIG. 3) and a sensing node may be precharged, a voltage of a sensing node may be developed according to a logic state of data stored in a memory cell, and data may be stored in a sensing latch LAT (e.g., LAT as illustrated in FIG. 4) connected to the sensing node according to the development of the voltage of the sensing node. The voltage Sel. vSO may be differently shown when a selected memory cell is an on-cell and the selected memory cell is an off-cell. If the voltage Sel. vSO is greater than a trip level, the sensing latch LAT may be tripped, and if the voltage Sel. vSO is less than the trip level, the sensing latch LAT may not be tripped.

The PVT variation of transistors involved in the trip operation of the sensing latch LAT may cause a variation of the trip level. The trip level variation may impede securing a required sensing margin (e.g., a sensing margin for a low-power operation). In some implementations, a trim voltage that trips the sensing latch LAT in an off-cell state may be applied to a trim transistor circuit TTC1, TTC2 of a sensing latch circuit SL, and a trip operation of the sensing latch circuit SL may be performed as the trim voltage is applied. Since the trip operation can be performed at the target trip level by applying the trim voltage, an effect of reducing the variation of the trip level may be achieved, and the sensing margin may be secured.

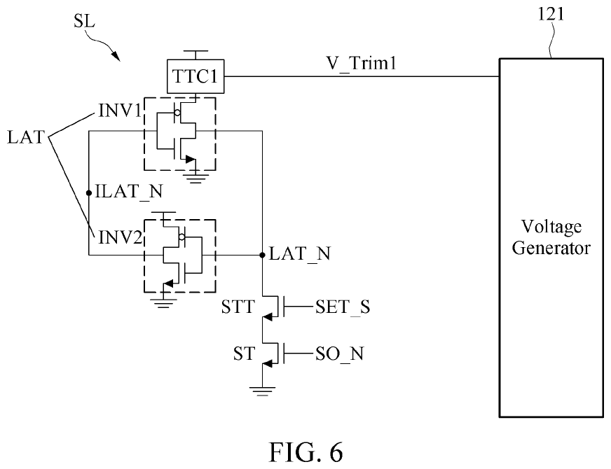

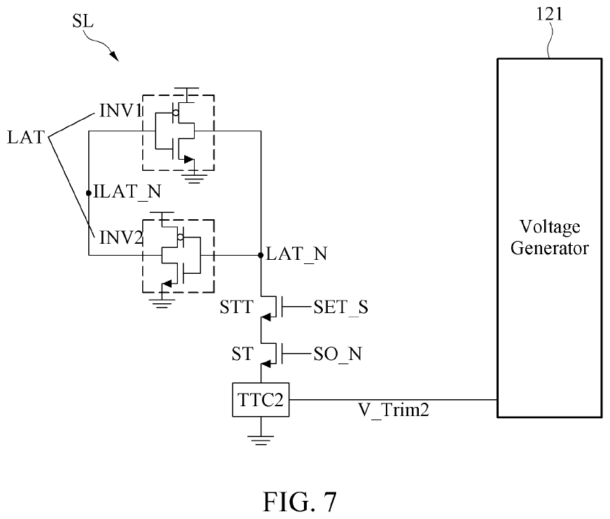

FIGS. 6 and 7 are circuit diagrams of an example configuration of a sensing latch circuit diagram having one of a first trim transistor circuit and a second trim transistor circuit according to some implementations. As described with reference to FIG. 4, the trim transistor circuit may include at least one of the first trim transistor circuit TTC1 and the second trim transistor circuit TTC2. FIG. 4 illustrates the sensing latch circuit SL including both of the first trim transistor circuit TTC1 and the second trim transistor circuit TTC2. FIG. 6 illustrates the sensing latch circuit SL that includes a first trim transistor circuit TTC1 and does not include the second trim transistor circuit TTC2 unlike FIG. 4, and FIG. 7 illustrates the sensing latch circuit SL that includes a second trim transistor circuit TTC2 and does not include the first trim transistor circuit TTC1.

Referring to FIG. 6, the sensing latch circuit SL may include to the sensing latch LAT including the first inverter INV1 and the second inverter INV2, and the first trim transistor circuit TTC1 that is electrically connected to the PMOS transistor of the first inverter INV1, and that is configured to adjust a trip level of the sensing latch LAT based on the first trim voltage V_Trim1. Referring to FIG. 7, the sensing latch circuit SL may include the sensing latch LAT disposed between the latch node LAT_N and the inverting latch node ILAT_N, the sensing transistor ST disposed between the latch node LAT_N and the ground terminal, and the second trim transistor circuit TTC2 that is connected to the sensing transistor ST in series and configured to adjust the trip level of the sensing latch LAT based on the second trim voltage V_Trim2.

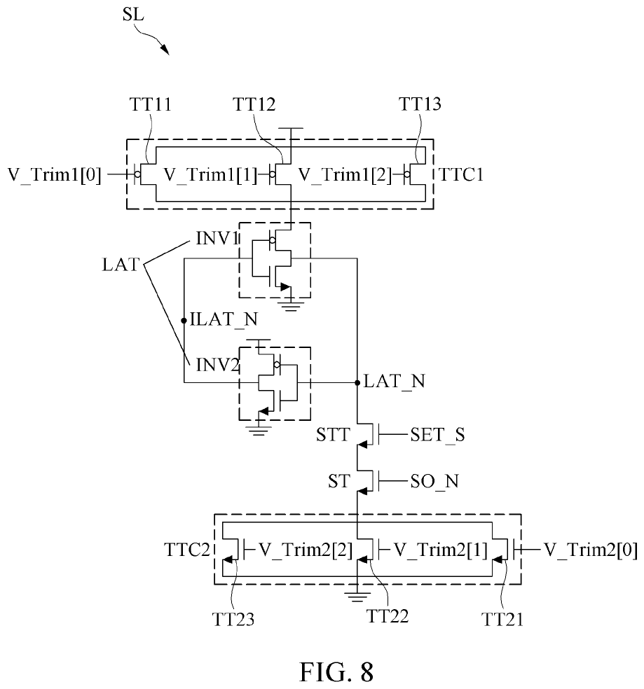

FIG. 8 is a circuit diagram of an example configuration of a sensing latch circuit using parallel trim transistors according to some implementations. Referring to FIG. 8, the first trim transistor circuit TTC1 may include first trim transistors TT11, TT12, and TT13 connected in parallel. The first trim transistors TT11, TT12, and TT13 may be connected to the PMOS transistor of the first inverter INV1 in parallel, and may each receive the first trim voltage V_Trim1[0:2] via a gate. The first trim transistors TT11, TT12, and TT13 may be PMOS transistors. The second trim transistor circuit TTC2 may include second trim transistors TT21, TT22, and TT23 connected in parallel. The second trim transistors TT21, TT21, and TT23 may be connected to the sensing transistor ST in parallel and may each receive a second trim voltage V_Trim2[0:2] via a gate. The second trim transistors TT21, TT22, and TT23 may be NMOS transistors. The first trim voltage V_Trim1[0:2] and the second trim voltage V_Trim2[0:2] may be digital signals and may be generated by a control logic (e.g., the control logic 123).

The first trim transistor circuit TTC1 and the second trim transistor circuit TTC2 may adjust the trip level of the sensing latch LAT using the first trim voltage V_Trim1[0:2] and the second trim voltage V_Trim2[0:2]. An on or off state of the first trim transistors TT11, TT12, and TT13 and the second trim transistors TT21, TT22, and TT23 may be individually controlled based on the first trim voltage V_Trim1[0:2] and the second trim voltage V_Trim2[0:2], and the trip level of the sensing latch LAT may be adjusted based on the on or off state of the first trim transistors TT11, TT12, and TT13 and the second trim transistors TT21, TT22, and TT23. For example, when a voltage corresponding to digital high is applied to the first trim transistors TT11, TT12, and TT13 and the second trim transistors TT21, TT22, and TT23, the first trim transistors TT11, TT12, and TT13 and the second trim transistors TT21, TT22, and TT23 may be in the on state. When a voltage corresponding to digital low is applied to the first trim transistors TT11, TT12, and TT13 and the second trim transistors TT21, TT22, and TT23, the first trim transistors TT11, TT12, and TT13 and the second trim transistors TT21, TT22, and TT23 may be in the off state.

The trim transistor circuit may include at least one of the first trim transistor circuit TTC1 and the second trim transistor circuit TTC2. FIG. 8 illustrates the sensing latch circuit SL including both the first trim transistor circuit TTC1 and the second trim transistor circuit TTC2. The sensing latch circuit SL may include the first trim transistor circuit TTC1 and may not include the second trim transistor circuit TTC2 as shown in FIG. 6, or may include the second trim transistor circuit TTC2 and may not include the first trim transistor circuit TTC1 as shown in FIG. 7.

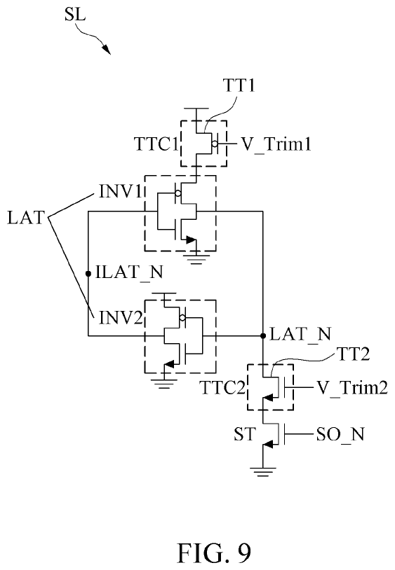

FIG. 9 is a circuit diagram of an example configuration of a sensing latch circuit diagram including a second trim transistor circuit positioned between a latch node and a sensing transistor according to some implementations. Referring to FIG. 9, the first trim transistor circuit TTC1 may include the first trim transistor TT1 disposed between a power terminal and the first inverter INV1 and configured to receive the first trim voltage V_Trim1 via a gate. The second trim transistor circuit TTC2 may include the second trim transistor TT2 disposed between the latch node LAT_N and the sensing transistor ST and configured to receive the second trim voltage V_Trim2 via a gate.

FIG. 9 illustrates the sensing latch circuit SL including both the first trim transistor circuit TTC1 and the second trim transistor circuit TTC2. The sensing latch circuit SL may include the first trim transistor circuit TTC1 and may not include the second trim transistor circuit TTC2 as shown in FIG. 6, or may include the second trim transistor circuit TTC2 and may not include the first trim transistor circuit TTC1 as shown in FIG. 7.

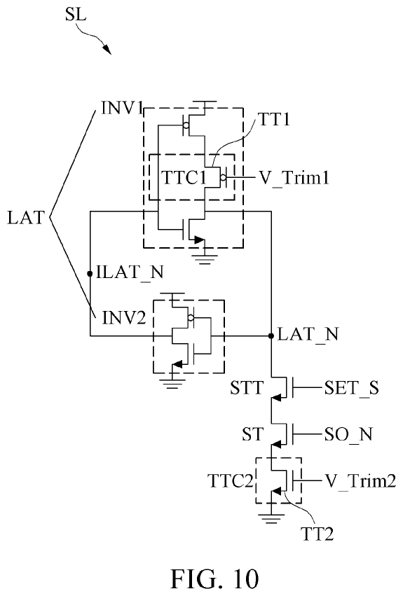

FIG. 10 is a circuit diagram of an example configuration of a sensing latch circuit diagram including a first trim transistor circuit positioned inside an inverter of a sensing latch according to some implementations. Referring to FIG. 10, the sensing latch LAT may include the first inverter INV1 and the second inverter INV2. The first inverter INV1 and the second inverter INV2 may each include a PMOS transistor and an NMOS transistor. The first trim transistor circuit TTC1 may include the first trim transistor TT1 disposed between a PMOS transistor of the first inverter INV1 and an NMOS transistor of the first inverter INV1. The first trim transistor TT1 may be electrically connected to the PMOS transistor of the first inverter INV1 and the NMOS transistor of the first inverter INV1. The second trim transistor TT2 may be disposed between the sensing transistor ST and the ground terminal.

FIG. 10 illustrates the sensing latch circuit SL including both the first trim transistor circuit TTC1 and the second trim transistor circuit TTC2. The sensing latch circuit SL may include the first trim transistor circuit TTC1 and may not include the second trim transistor circuit TTC2 as shown in FIG. 6, or may include the second trim transistor circuit TTC2 and may not include the first trim transistor circuit TTC1 as shown in FIG. 7.

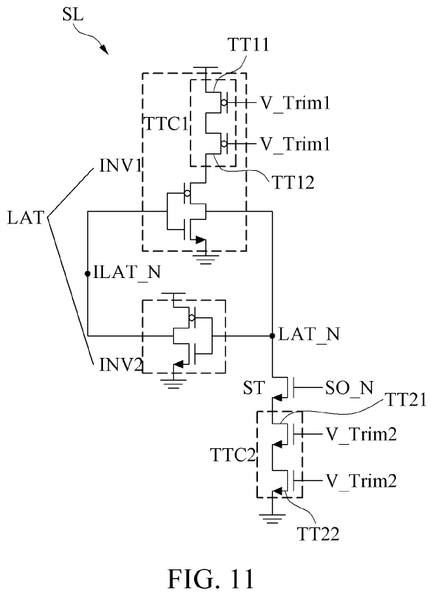

FIG. 11 is a circuit diagram of an example configuration of a sensing latch circuit diagram including a first trim transistor circuit and a second trim transistor circuit each including at least one trim transistor, according to some implementations. Referring to FIG. 11, the first trim transistor circuit TTC1 may include first trim transistors TT11 and TT12 connected in series. The first trim transistors TT11 and TT12 may be connected to the PMOS transistor in series and may each receive the first trim voltage V_Trim1 via a gate. The second trim transistor circuit TTC2 may include the second trim transistors TT21 and TT22 connected in series. The second trim transistors TT21 and TT22 may be connected to the sensing transistor ST in series and may each receive the second trim voltage V_Trim2 via a gate.

FIG. 11 illustrates the sensing latch circuit SL including both the first trim transistor circuit TTC1 and the second trim transistor circuit TTC2. The sensing latch circuit SL may include the first trim transistor circuit TTC1 and may not include the second trim transistor circuit TTC2 as shown in FIG. 6, or may include the second trim transistor circuit TTC2 and may not include the first trim transistor circuit TTC1 as shown in FIG. 7.

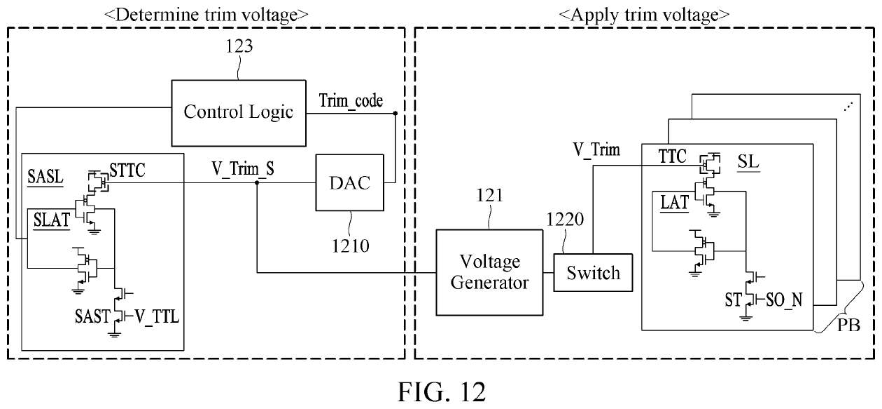

FIG. 12 is a circuit diagram of an example configuration performing a calibration procedure using a sample sensing latch circuit according to some implementations. Referring to FIG. 12, a memory device (e.g., the memory device 100 of FIG. 1) may include a sample sensing latch circuit SASL corresponding to the sensing latch circuit SL (e.g., SL of FIGS. 4 and 6-11). The sample sensing latch circuit SASL may have the same configuration and the same structure as the sensing latch circuit SL. The sample sensing latch circuit SASL may include a sample sensing latch SLAT corresponding to the sensing latch LAT and a sample trim transistor circuit STTC corresponding to the trim transistor circuit TTC (e.g, TTC 1, TTC2 of FIGS. 4 and 6-11).

In some implementations, a calibration procedure to determine the trim voltage V_Trim is performed. The calibration procedure may be performed once, periodically, or aperiodically. For example, the calibration procedure may be performed at a predetermined time (e.g., chip driving time, wafer production time, etc.). If the calibration is performed at the chip driving time, a trip level variation due to a temperature change may be compensated. If the calibration is performed on each wafer at the wafer production time, a trip level variation according to the process characteristics of each wafer may be compensated. As another example, the calibration procedure may be performed at a predetermined calibration cycle. As another example, the calibration procedure may be performed when a predetermined condition (e.g., a temperature change, a voltage change, etc.) is satisfied. In the calibration procedure, the control logic 123 may determine the trim voltage V_Trim using the sample sensing latch circuit SASL.

In the calibration procedure, a voltage V_TTL of a target trip level may be applied to a sample sensing transistor SAST of the sample sensing latch circuit SASL, as shown in FIG. 12. The control logic 123 may provide a sample trim voltage V_Trim_S to the sample trim transistor circuit STTC of the sample sensing latch SLAT and adjust the sample trim voltage V_Trim_S while the voltage V_TTL of the target trip level is applied to the sample sensing transistor SAST. For example, the control logic 123 may sequentially increase or decrease the sample trim voltage V_Trim_S.

The control logic 123 may adjust the sample trim voltage V_Trim_S using trim code Trim_code. The memory device 100 may include a digital-to-analog converter (DAC) 1210, the voltage generator 121, and a switch 1220. The control logic 123 may generate trim code Trim_code. The trim code Trim_code may be an n-bit digital control signal. The DAC 1210 may convert the trim code Trim_code into the sample trim voltage V_Trim_S. The control logic 123 may adjust the sample trim voltage V_Trim_S by changing the trim code Trim_code.

A trip operation of the sample sensing latch SLAT may be caused by the adjusted sample trim voltage V_Trim_S. When the trip operation of the sample sensing latch SLAT occurs, the control logic 123 may store the trim code Trim_code of the sample trim voltage V_Trim_S that causes the trip operation of the sample sensing latch SLAT as a calibration result.

In some implementations, the sample sensing latch circuit LA includes both a first sample trim transistor circuit TTC1 and a second sample trim transistor circuit TTC2 (e.g., corresponding to the sensing latch circuit SL in FIG. 9). The sample trim voltage V_Trim_S can include at least one first sample trim voltage V_Trim1_S and/or at least one second sample trim voltage V_Trim2_S. In some implementations, the first sample trim transistor circuit STTC1 includes two or more sample first trim transistors (e.g., corresponding to the sensing latch circuit SL in FIG. 8), and the first sample trim voltages V_Trim1_S that cause the trip operation can be different for different sample first trim transistors.

When the calibration procedure is terminated, the control logic 123 may provide the stored trim code Trim code to the DAC 1210. The DAC 1210 may convert the trim code Trim_code into the sample trim voltage V_Trim_S. The voltage generator 121 may generate the trim voltage V_Trim by amplifying the sample trim voltage V_Trim_S.

The sensing latch circuit SL and the sample sensing latch circuit SASL may be manufactured on the same wafer. The PVT variation of the sensing latch circuit and the PVT variation of the sample sensing latch circuit SASL may have corresponding levels. Therefore, a trip operation of the sensing latch circuit SL may be induced by a trim voltage that trips the sample sensing latch circuit SASL.

The switch 1220 may enable or disable the trim transistor circuit TTC. To enable the trim transistor circuit TTC, the switch 1220 may provide the trim voltage V_Trim to the trim transistor circuit TTC. To disable the trim transistor circuit TTC, the switch 1220 may provide a weak voltage (e.g., a voltage to turn off the PMOS transistor) to the trim transistor circuit TTC. When the trim transistor circuit TTC is disabled, page buffers PB may operate as if the trim transistor circuit TTC does not exist. The switch 1220 may operate under the control of the control logic 123.

When the calibration procedure is terminated, the sample sensing latch circuit SASL may be disabled to reduce the power consumption. For example, a constant current that occurs when the sample sensing latch SLAT is flipped may be reduced by weakening the PMOS transistor by applying a bias to a gate of the PMOS transistor of the inverter of the sample sensing latch SLAT. In addition, system power consumption and power noise of the page buffers PB may be reduced. As another example, an off-state current of the sensing latch LAT may be reduced when a chip is in a standby state by applying a bias to the gate of the PMOS transistor of the inverter of the sample sensing latch SLAT. The standby power of the chip may be reduced by suppressing a gate induced drain leakage (GIDL) current of the sensing latch LAT.

As described with reference to FIG. 8, the trim voltage V_Trim may correspond to a digital signal. In such cases, the DAC 1210 may not be used. The trim voltage V_Trim may correspond to the sample trim voltage V_Trim_S. In the calibration procedure, the control logic 123 may find the trim code Trim_code that trips the sample sensing latch SLAT at the target trip level and may store the trim code. When the calibration procedure is terminated, the control logic 123 may provide the stored trim code Trim_code to the voltage generator 121 associated with the sample trim voltage V_Trim_S. The voltage generator 121 may generate the trim voltage V_Trim by amplifying the sample trim voltage V_Trim_S.

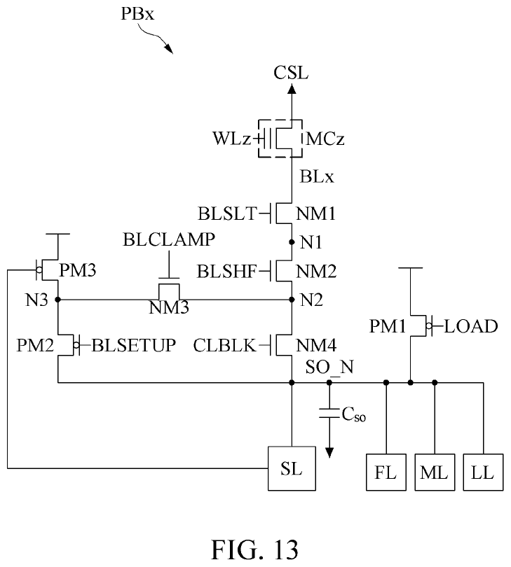

FIG. 13 is a circuit diagram of an example configuration of a page buffer according to some implementations. Referring to FIG. 13, an x-th page buffer PBx may be connected to an x-th bit line BLx. A z-th memory cell MCz, which is a selected memory cell sMC, may be connected to the x-th bit line BLx. A z-th word line WLz, which is a selected word line sWL, may be connected to the z-th memory cell MCz. The x-th bit line BLx may be connected to a common source line CSL through the z-th memory cell MCz.

A first NMOS transistor NM1 may be included between the x-th bit line BLx and a first node N1. The first NMOS transistor NM1 may be a bit line selection transistor driven by a bit line selection signal BLSLT. The bit line selection transistor may be implemented as a high voltage transistor. The bit line selection transistor may be disposed in a high voltage area.

A second NMOS transistor NM2 may be included between the first node N1 and a second node N2. The second NMOS transistor NM2 may be a bit line shut-off transistor driven by a bit line shut-off signal BLSHF. A third NMOS transistor NM3 may be included between the second node N2 and a third node N3. The third NMOS transistor NM3 may be a bit line clamping transistor driven by a bit line clamping control signal BLCLAMP. A fourth NMOS transistor NM4 may be included between the second node N2 and a sensing node SO_N. The fourth NMOS transistor NM4 may be a bit line connection transistor driven by a bit line connection control signal CLBLK.

A first PMOS transistor PM1 may be included between the sensing node SO_N and a power terminal. The first PMOS transistor PM1 may be a precharge load transistor driven by a load signal LOAD. A second PMOS transistor PM2 may be included between the sensing node SO_N and the third node N3. The second PMOS transistor PM2 may be a bit line setup transistor driven by a bit line setup signal BLSETUP. A third PMOS transistor PM3 may be included between the third node N3 and the power terminal. The third PMOS transistor PM3 may be a precharge transistor driven by an inverting latch node.

The sensing latch circuit SL, a force latch circuit FL, an upper bit latch circuit ML, and a lower bit latch circuit LL may be connected to the sensing node SO_N. The sensing latch circuit SL may store data stored in the selected memory cell sMC or a sensing result of a threshold voltage of the selected memory cell sMC during a read or program verify operation. In addition, the sensing latch circuit SL may be used to apply a program bit line voltage or a program prohibition voltage to the x-th bit line BLx during the program operation. The force latch circuit FL may be used to improve a threshold voltage distribution during the program operation. The upper bit latch circuit ML and the lower bit latch circuit LL may be used to store data input from the outside during the program operation.

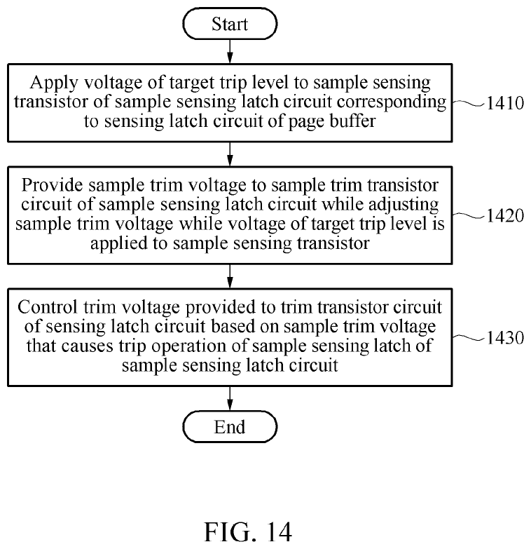

FIG. 14 is a flowchart illustrating an example of a method performed by a memory device according to some implementations. Referring to FIG. 14, in operation 1410, the memory device may apply a voltage of a target trip level to a sample sensing transistor of a sample sensing latch circuit corresponding to a sensing latch circuit of a page buffer. In operation 1420, the memory device may provide a sample trim voltage to a sample trim transistor circuit of the sample sensing latch circuit and adjust the sample trim voltage while the voltage of the target trip level is applied to the sample sensing transistor. In operation 1430, the memory device may control a trim voltage provided to a trim transistor circuit of the sensing latch circuit based on the sample trim voltage that causes a trip operation of the sample sensing latch of the sample sensing latch circuit at the target trip level

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although various examples have been described with reference to the accompanying drawings, concepts described herein can be carried out in other specific forms without departing from the scope of this disclosure. Therefore, the above examples should be considered illustrative. For example, suitable results may be achieved if the techniques disclosed in present disclosure are performed in a different order and/or if components in a described system, architecture, device, or circuit are combined in a different manner and/or replaced or supplemented by other components or their equivalents.

What is claimed is:

1. A memory device comprising:
a cell string comprising memory cells; and
a page buffer connected to the cell string through a bit line and comprising a sensing latch circuit, the page buffer configured to sense data of a selected memory cell of the memory cells through the sensing latch circuit,
wherein the sensing latch circuit comprises:
a sensing latch comprising a first inverter and a second inverter; and
a trim transistor circuit electrically connected to a p-type metal oxide semiconductor (PMOS) transistor of the first inverter and configured to adjust a trip level of the sensing latch based on a trim voltage.

2. The memory device of claim 1, wherein the trim transistor circuit comprises
a trim transistor disposed between a power terminal and the PMOS transistor of the first inverter.

3. The memory device of claim 1, wherein the trim transistor circuit comprises
a trim transistor disposed between the PMOS transistor of the first inverter and an n-type metal oxide semiconductor (NMOS) transistor of the first inverter.

4. The memory device of claim 1, wherein the trim transistor circuit comprises trim transistors connected in parallel.

5. The memory device of claim 1, wherein the trim transistor circuit comprises trim transistors connected in series.

6. The memory device of claim 1, further comprising:
a sample sensing latch circuit comprising a sample sensing latch corresponding to the sensing latch and a sample trim transistor circuit corresponding to the trim transistor circuit; and
a control logic configured to determine the trim voltage through the sample sensing latch circuit.

7. The memory device of claim 6, wherein the control logic is configured to provide a sample trim voltage to the sample trim transistor circuit, adjust the sample trim voltage while a voltage of a target trip level is being applied to a sample sensing transistor of the sample sensing latch circuit, and control the trim voltage based on the adjusted sample trim voltage that causes a trip operation of the sample sensing latch at the target trip level.

8. A memory device comprising:
a cell string comprising memory cells; and
a page buffer connected to the cell string through a bit line and comprising a sensing latch circuit, the page buffer configured to sense data of a selected memory cell of the memory cells through the sensing latch circuit,
wherein the sensing latch circuit comprises:
a sensing latch disposed between a latch node and an inverting latch node;
a sensing transistor disposed between the latch node and a ground terminal; and
a trim transistor circuit connected to the sensing transistor in series and configured to adjust a trip level of the sensing latch based on a trim voltage.

9. The memory device of claim 8, wherein the trim transistor circuit comprises
a trim transistor disposed between the sensing transistor and the ground terminal.

10. The memory device of claim 8, wherein the trim transistor circuit comprises
a trim transistor disposed between the latch node and the sensing transistor.

11. The memory device of claim 8, wherein the trim transistor circuit comprises
trim transistors connected in parallel.

12. The memory device of claim 8, wherein the trim transistor circuit comprises
trim transistors connected in series.

13. The memory device of claim 8, further comprising:
a sample sensing latch circuit comprising a sample sensing latch corresponding to the sensing latch and a sample trim transistor circuit corresponding to the trim transistor circuit; and
a control logic configured to determine the trim voltage through the sample sensing latch circuit.

14. The memory device of claim 13, wherein the control logic is configured to provide a sample trim voltage to the sample trim transistor circuit, adjust the sample trim voltage while a voltage of a target trip level is being applied to a sample sensing transistor of the sample sensing latch circuit, and control the trim voltage based on the adjusted sample trim voltage that causes a trip operation of the sample sensing latch at the target trip level.

15. A memory device comprising:
a cell string comprising memory cells; and
a page buffer connected to the cell string through a bit line and comprising a sensing latch circuit, the page buffer configured to sense data of a selected memory cell of the memory cells through the sensing latch circuit,
wherein the sensing latch circuit comprises:
a sensing latch disposed between a latch node and an inverting latch node and comprising a first inverter and a second inverter;
a sensing transistor disposed between the latch node and a ground terminal; and
a trim transistor circuit configured to adjust a trip level of the sensing latch based on a trim voltage,
wherein the trim transistor circuit comprises:
a first trim transistor circuit electrically connected to a p-type metal oxide semiconductor (PMOS) transistor of the first inverter, and
a second trim transistor circuit electrically connected to the sensing transistor.

16. The memory device of claim 15, wherein the first trim transistor circuit comprises:
a first trim transistor disposed between a power terminal and the PMOS transistor of the first inverter or between the PMOS transistor of the first inverter and an n-type metal oxide semiconductor (NMOS) transistor of the first inverter.

17. The memory device of claim 15, wherein the second trim transistor circuit comprises:
a second trim transistor disposed between the sensing transistor and the ground terminal or between the latch node and the sensing transistor.

18. The memory device of claim 15, wherein the first trim transistor circuit comprises first trim transistors connected in parallel, or
the second trim transistor circuit comprises second trim transistors connected in parallel.

19. The memory device of claim 15, wherein the first trim transistor circuit comprises first trim transistors connected in series, or
the second trim transistor circuit comprises second trim transistors connected in series.

20. The memory device of claim 15, further comprising:
a sample sensing latch circuit comprising a sample sensing latch corresponding to the sensing latch and a sample trim transistor circuit corresponding to the trim transistor circuit; and
a control logic configured to determine the trim voltage using the sample sensing latch circuit.
